(19) United States
(12) Patent Application Publication
(10) Pub. No.: US 2011/0114178 A1
(43) Pub. Date: May 19, 2011

(54) SOLAR CELL MODULE

(75) Inventors: Yu-Ting LIN, Hsinchu City (TW); Wen-Kai Hsu, Zhubei City (TW); Shih-Che Huang, Chiayi City (TW)

(73) Assignee: Du Pont Apollo Limited, Hong Kong (HK)

(21) Appl. No.: 12/945,909

(22) Filed: Nov. 15, 2010

Related U.S. Application Data
(60) Provisional application No. 61/261,892, filed on Nov. 17, 2009.

(51) Int. Cl. H01L 31/0256

(52) U.S. Cl. 136/258; 136/252

(57) ABSTRACT

Disclosed herein is a solar cell module, which includes a photovoltaic member, a back transparent substrate and an ink layer. The photovoltaic member is capable of converting light into electricity. The ink layer is disposed between the photovoltaic member and the transparent back substrate, and can be observed through the back transparent substrate. The ink layer may exhibit a colorful picture or pattern.

### RELATED APPLICATIONS

This application claims priority to U.S. Provisional Application Ser. No. 61/261,892, filed Nov. 17, 2009, which is herein incorporated by reference.

### BACKGROUND

1. Field of Invention

The present invention relates to a photovoltaic module. More particularly, the present invention relates to a solar cell module with an ink layer.

2. Description of Related Art

Solar energy has gained many research attentions for being a seemingly inexhaustible energy source. Solar cells are devices developed for such purpose by converting solar energy directly into electrical energy.

Currently, solar cells are often made of single crystalline silicon and poly crystalline silicon, and such devices account for more than 90% of the solar cell market. However, production of these types of solar cells would require high quality silicon wafers, thereby rendering the manufacturing process cost in-effective. Furthermore, silicon wafer based-solar cells are not suitable for certain application such as transparent glass curtain and other building integrated photovoltaic (BIPV). Therefore, thin film solar cells, particularly, see-through type thin film solar cells, are employed in the aforementioned application.

A conventional see-through type thin film solar cell module includes a glass substrate, a transparent electrode, a photoelectric conversion layer and a back contact. The transparent electrode is formed on the glass substrate. The photoelectric conversion layer is disposed on the transparent electrode. Moreover, the back contact is disposed on the photoelectric conversion layer by position displacement, and is in contact with the underlying transparent electrode. Unfortunately, when this type of solar cells are used as window glass in a house or building, re-decoration of the window glass to avoid a dull look becomes indispensable and further lowers the incentives in purchasing such devices. Therefore, there exits in this art a need of improved solar devices that are free of the aforementioned problems.

### SUMMARY

The present disclosure provides a solar cell module characterized in having an ink layer. The solar cell module includes a photovoltaic member, a back transparent substrate and an ink layer. The photovoltaic member is capable of converting light into electricity. The ink layer is disposed between the photovoltaic member and the transparent back substrate, and can be observed through the back transparent substrate. The ink layer may exhibit a colorful picture or pattern.

According to one embodiment of the present disclosure, the solar cell module may include a first sealing member disposed between the ink layer and the photovoltaic member, wherein the first sealing member may be a layer of ethylene-vinyl acetate copolymer (EVA).

According to another embodiment of the present disclosure, the ink layer may consist of one layer or multiple layers. In one example, the ink layer include a first ink layer disposed on the photovoltaic member and a second ink layer disposed on the first ink layer, and wherein the first ink layer has a single color and the second ink layer has multiple colors.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view of one embodiment of the present disclosure;

FIG. 2 is a cross-sectional view of another embodiment of the present disclosure; and

FIG. 3 is a cross-sectional view of still another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

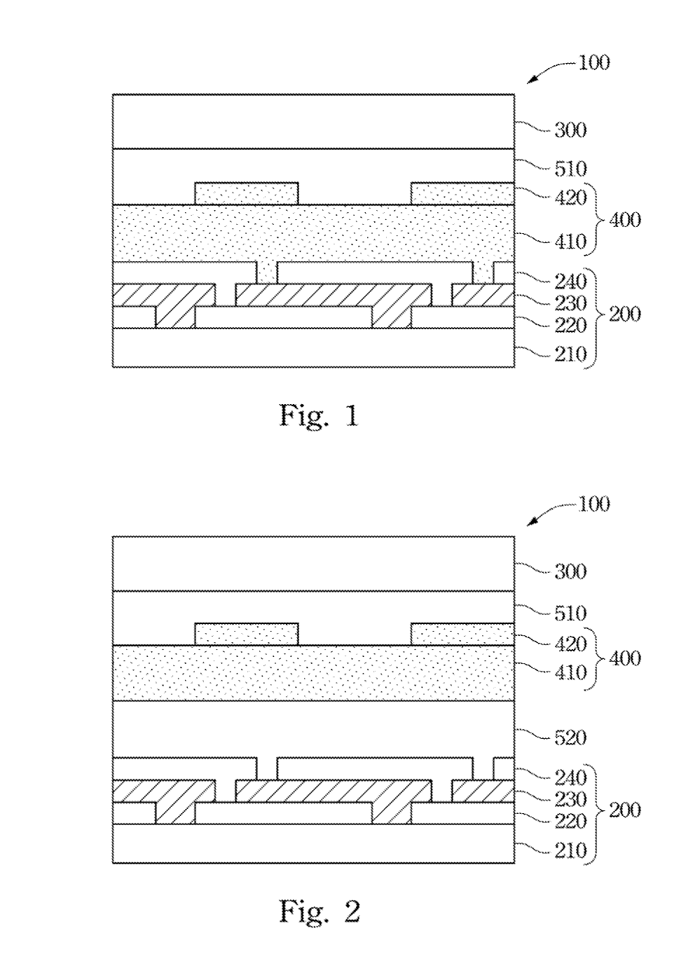

FIG. 1 is a cross-sectional view of a solar cell module 100 according to one embodiment of the present disclosure. As shown in FIG. 1, the solar cell module 100 includes a photovoltaic member 200, a back transparent substrate 300 and an ink layer 400. The photovoltaic member 200 is capable of converting light into electricity, and is described in detail hereinafter.

The ink layer 400 is disposed between the photovoltaic member 200 and the transparent back substrate 300. Further, the ink layer 400 can be observed through the back transparent substrate 300. In one example, the ink layer 400 is disposed on the photovoltaic member 200. The method of forming the ink layer 400 includes, but is not limited to, screen printing, ink jet printing, offset printing, relief printing, and intaglio printing. The ink layer 400 may consist of a single layer or multiple layers. In one example, the ink layer 400 includes a first ink layer 410 and a second ink layer 420. The first ink layer 410 may have a single color and is formed directly on the photovoltaic member 200 so as to mask the original color of the photovoltaic member 200. The second ink layer 420 may be formed on the first ink layer 410 and exhibits a vivid and colorful image or picture. The image or picture may be observed through the back transparent substrate 300.

In one embodiment, solar cell module 100 may further include a first sealing member 510 disposed between the ink layer 400 and the back transparent substrate 300. The back transparent substrate 300 may be adhered to ink layer 400 by the first sealing member 510. For the purpose of exhibiting the color of the ink layer, the first sealing member 510 may has good transparency. The first sealing member 510 serves not only to protect the photovoltaic member 200 from external environments such as temperature variations, humidity and shocks, but also to bond the back transparent substrate 300 to the ink layer 400 and the photovoltaic member 200. In one example, the first sealing member 510 comprises ethylene-vinyl acetate copolymer (also known as EVA), which has good transparency and gloss, good stress-crack resistance, and good UV radiation resistance.

There is no specific limitation on the material of the back transparent substrate 300, so long as it is capable of excellent strength, weather resistance, UV resistance and moisture barrier properties and is transparent to visible light. For example, the back transparent substrate 300 may be made of glass or other transparent plastics such as polystyrene and polycarbonate. The back transparent substrate 300 may protect the ink layer 400 and the photovoltaic member 200 from damage, and may further prevent mist and pollutions from leaking into the solar cell module 100.

The photovoltaic member 200 is used for converting light into electricity. In one embodiment, the photovoltaic member 200 includes form top to bottom, a front transparent substrate 210, a transparent conductive layer 220, a photoelectric conversion layer 230 and a back conductive layer 240, as depicted in FIG. 1.

Usually, light is transmitted through the front transparent substrate 210 and the transparent conductive layer 220, and is subsequently absorbed by the photoelectric conversion layer 230. The material of the front transparent substrate 210 may be same as or different from the back transparent substrate 300. Typically, the front transparent substrate 210 is set in the outdoors, and thus requires a good resistance to the strict weather conditions. In one example, the front transparent substrate 210 is made of glass.

The transparent conductive layer 220 is disposed on the front transparent substrate 210. In one example, the transparent conductive layer 220 is a transparent conductive oxide layer. For example, the transparent conductive oxide layer may include zinc oxide (ZnO), fluorine doped tin dioxide (SnO₂:F), or indium tin oxide (ITO). In some examples, pyramid-like structures or textured structures (not shown) are formed on the surface of the transparent conductive layer 220 to enhance the efficiency of the solar cell.

The photoelectric conversion layer 230 is disposed on the transparent conductive layer 220. In some examples, the photoelectric conversion layer 230 includes a p-i-n structure composed of a p-type semiconductor, an intrinsic semiconductor and an n-type semiconductor (not shown). The intrinsic semiconductor, also called an undoped semiconductor, is a pure semiconductor without any significant dopant species present. In these examples, the material of these semiconductors may include amorphous silicon. When the photoelectric conversion layer 230 absorbs light, electron-hole pairs are generated therein, and then the electron-hole pairs are separated by the electric field established in the photoelectric conversion layer 230 to form electric current.

The back conductive layer 240 is disposed on the photoelectric conversion layer 230. In some examples, the back conductive layer 240 may include silver, aluminum, copper, chromium or nickel. The back conductive layer 240 and the transparent conductive layer 220 are capable of transmitting the electric current generated by the photoelectric conversion layer 230 to an external loading device (not shown).

Referring to FIG. 2, which is a cross-sectional view of a solar cell module 100 according to another embodiment of the present disclosure. The solar cell module 100 includes a photovoltaic member 200, a back transparent substrate 300 and an ink layer 400, a first sealing member 510, and a second sealing member 520. In this embodiment, the photovoltaic member 200 may has a structure same as the photovoltaic member in FIG. 1. Moreover, both the ink layer 400 and the back transparent substrate 300 may be the same as that described in FIG. 1. The first sealing member 510 is disposed between the ink layer 400 and the back transparent substrate 300. The second sealing member 520 is disposed between the ink layer 400 and the photovoltaic member 200. The first and second sealing members 510, 520 adhere the back transparent substrate 300, the ink layer 400 and the photovoltaic member 200 together, and form a single module. The ink layer 400 composed of a single layer or multiple layers may be observed through the first sealing member 510 and the back transparent substrate 300. In this embodiment, the second sealing member 520 does not require good transparency. If desired, the second sealing member 520 may be same as the first sealing member 510.

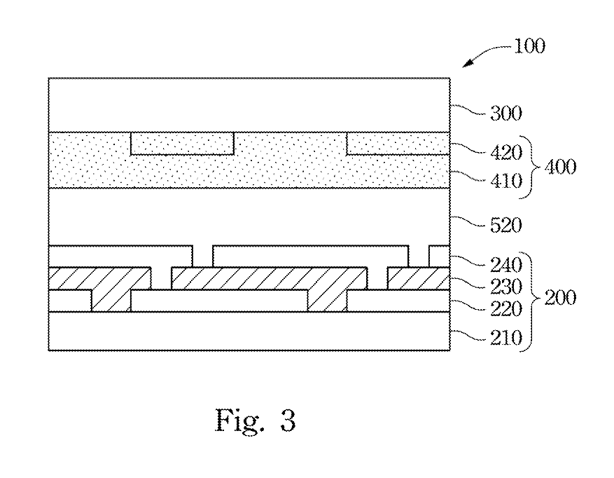

Referring to FIG. 3, which is a cross-sectional view of a solar cell module 100 according to still another embodiment of the present disclosure. The solar cell module 100 includes a photovoltaic member 200, a back transparent substrate 300 and an ink layer 400 and a second sealing member 520. In this embodiment, the structures and the materials of the photovoltaic member 200, the back transparent substrate 300 and the ink layer 400 may be same as those described hereinbefore. However, the ink layer 400 composed of single layer or multiple layers is formed on the back transparent substrate 300 directly, and may be observed through the back transparent substrate 300. The back transparent substrate 300 having the ink layer 400 is adhered on the photovoltaic member 200 by the second sealing member 520.

The solar cell module disclosed herein may exhibit a colorful picture or pattern. When the solar cell module is integrated within a window glass, it may provide a colorful pattern in the room and becomes part of a decoration. Furthermore, the ink layer covered the photovoltaic member may also prevent the photovoltaic member from oxidation or erosion.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell module, comprising:
a photovoltaic member for converting light into electricity;
a back transparent substrate; and
an ink layer disposed between the photovoltaic member and the back transparent substrate, wherein the ink layer can be observed through the back transparent substrate.

2. The solar cell module according to claim 1, further comprising a first sealing member disposed between the ink layer and the photovoltaic member.

3. The solar cell module according to claim 2, wherein the first sealing member comprises ethylene-vinyl acetate copolymer.

4. The solar cell module according to claim 1, further comprising a second sealing member disposed between the ink layer and the back transparent substrate.

5. The solar cell module according to claim 1, wherein the ink layer is disposed on the photovoltaic member.

6. The solar cell module according to claim 5, wherein the ink layer comprises a first ink layer disposed on the photovoltaic member and a second ink layer disposed on the first ink layer, and wherein the first ink layer has a single color and the second ink layer has multiple colors.

7. The solar cell module according to claim 1, wherein the photovoltaic member comprises from bottom to top:
a back conductive layer disposed above the ink layer;
a photoelectric conversion layer disposed on the back conductive layer;
a transparent conductive layer disposed on the photoelectric conversion layer; and
a front transparent substrate disposed on the transparent conductive layer.

8. The solar cell module according to claim 7, wherein the transparent conductive layer is a transparent conductive oxide layer.

9. The solar cell module according to claim 8, wherein the transparent conductive oxide layer comprises at least one material selected from the group consisting of zinc oxide (ZnO), fluorine doped tin dioxide (SnO₂:F), and Indium tin oxide (ITO).

10. The solar cell module according to claim 7, wherein the photoelectric conversion layer comprises amorphous silicon.

11. The solar cell module according to claim 7, wherein the back conductive layer comprises at least one material selected from the group consisting of silver, aluminum, copper, chromium and nickel.
